(19) United States
(12) Patent Application Publication
(10) Pub. No.: US 2013/0146343 A1
(43) Pub. Date: Jun. 13, 2013

(54) PRINTED CIRCUIT BOARD AND METHOD OF MANUFACTURING THE SAME

(71) Applicant: SAMSUNG ELECTRO-MECHANICS CO., LTD., Gyunggi-do (KR)

(72) Inventor: Su Il Kim, Gyunggi-do (KR)

(73) Assignee: SAMSUNG ELECTRO-MECHANICS CO., LTD., Gyunggi-do (KR)

(21) Appl. No.: 13/686,774

(22) Filed: Nov. 27, 2012

(30) Foreign Application Priority Data
Dec. 12, 2011 (KR) 10-2011-0133193

(51) Int. Cl. H05K 1/02; H05K 1/09; H05K 3/44

(52) U.S. Cl. CPC H05K 1/02; H05K 3/44; H05K 1/09
USPC 174/257; 174/250; 174/259; 29/829

(57) ABSTRACT

Disclosed herein are a printed circuit board and a method of manufacturing the same. The printed circuit board includes: an insulating layer; a first metal layer formed on the insulating layer; a second metal layer formed on a portion of the first metal layer; and an oxidation layer formed on a portion of the first metal layer on which the second metal layer is not formed, wherein materials of the first and second metal layers are different from each other, and the second metal layer is made of a material of which ionization tendency is smaller than that of the first metal layer.

### CROSS REFERENCE TO RELATED APPLICATION

This application claims the benefit of Korean Patent Application No. 10-2011-0133193, filed on Dec. 12, 2011, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

As disclosed in Document 1, a solder resist, which is a polymer material, is applied to a printed circuit board in order to protect the outermost layer of the printed circuit board from electrical impact, thermal impact, physical impact, and chemical impact from the outside.

After the solder resist is applied to the printed circuit board, an open part is formed in the solder resist by exposure and phenomenon processes, gold (Au) plating is performed in a wire bonding region, and copper is exposed in a solder ball pad region.

However, the solder resist has a problem that adhesion between the solder resist and a molding member becomes weak at the time of a packaging process, or the like, such that it has an effect on reliability of a product.
[Document 1] KR 10-0905922 (Jun. 26, 2009)

### SUMMARY OF THE INVENTION

The present invention has been made in an effort to provide a printed circuit board to which an improved process is applied in order to protect the outermost layer of a printed circuit board, and a method of manufacturing the same.

According to a preferred embodiment of the present invention, there is provided a printed circuit board including: an insulating layer; a first metal layer formed on the insulating layer; a second metal layer formed on a portion of the first metal layer; and an oxidation layer formed on a portion of the first metal layer on which the second metal layer is not formed, wherein materials of the first and second metal layers are different from each other, and the second metal layer is made of a material of which ionization tendency is smaller than that of the first metal layer.

The first metal layer may be made of a copper material.

The second metal layer may be made of a gold or nickel material.

The oxidation layer may be formed by a brown oxidation process.

The insulating layer may include a unit region and a dummy region.

The printed circuit board may further include an adhesive layer formed between the first and second metal layers.

According to another preferred embodiment of the present invention, there is provided a method of manufacturing a printed circuit board, the method including: preparing an insulating layer; forming a first metal layer on the insulating layer; forming a second metal layer on a portion of the first metal layer; forming a protection layer on the second metal layer; forming an oxidation layer on a portion of the first metal layer on which the protection layer is not formed; and removing the protection layer, wherein materials of the first and second metal layers are different from each other, and the second metal layer is made of a material of which ionization tendency is smaller than that of the first metal layer.

In the forming of the first metal layer, the first metal layer may be made of a copper material.

In the forming of the second metal layer, the second metal layer may be made of a gold or nickel material.

In the forming of the oxidation layer, the oxidation layer may be formed by a brown oxidation process.

The insulating layer may include a unit region and a dummy region.

The method may further include, after the forming of the first metal layer and before the forming of the second metal layer, forming an adhesive layer between the first and second metal layers.

In the forming of the protection layer, the protection layer may be a dry film

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view showing a configuration of a printed circuit board according to a preferred embodiment of the present invention; and

FIGS. 2 to 5 are plan views sequentially showing the process of a method of manufacturing the printed circuit board of FIG. 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted. Hereinafter, preferred embodiments of the present invention will be described in detail with reference to the attached drawings.

Printed Circuit Board

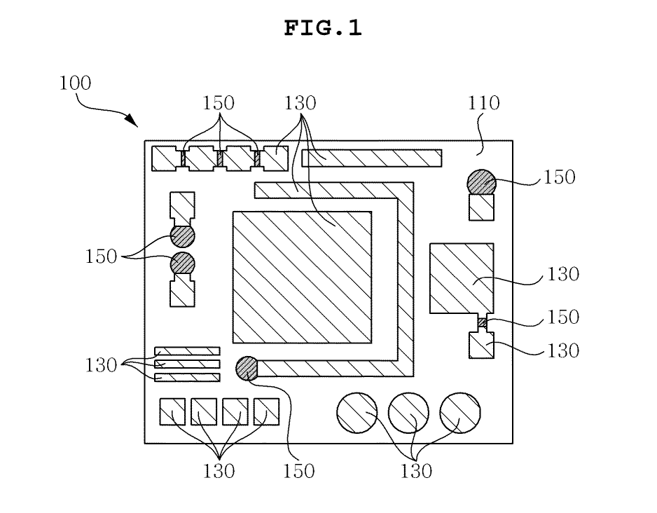

FIG. 1 is a plan view showing a configuration of a printed circuit board according to a preferred embodiment of the present invention.

As shown in FIG. 1, the printed circuit board 100 may be configured to include an insulating layer 110, a first metal layer 120 formed on the insulating layer 110, a second metal layer 130 formed on a portion of the first metal layer 120, and an oxidation layer 150 formed on a portion of the first metal layer on which the second metal layer 130 is not formed.

Here, as the insulating layer 110, a resin insulating layer may be used As materials of the resin insulating layer, a thermosetting resin such as an epoxy resin, a thermoplastic resin such as a polyimide resin, a resin having a reinforcement material such as a glass fiber or an inorganic filler impregnated in them, for example, a prepreg may be used. In addition, a photo-setting resin, and the like, may be used However, the materials of the resin insulating layer are not specifically limited thereto.

In addition, materials of the first and second metal layers 120 and 130 may be different from each other.

Further, the second metal layer 130 may be made of a material of which ionization tendency is smaller than that of the first metal layer 120.

Although the first metal layer 120 is not shown in FIG. 1 for convenience of explanation, it may be sufficiently analogized that the first metal layer 120 is formed beneath the second metal layer 130 or is formed before the oxidation layer 150 is formed, such that illustration of the first metal layer 120 is omitted.

The reason is that the second metal layer 130 is formed on a portion of the first metal layer 120 and the oxidation layer 150 is formed on a portion of the first metal layer 120 exposed since the second metal layer 130 is not formed, as described in the following description of a process of manufacturing a printed circuit board.

In addition, the first metal layer 120 may be made of a copper (Cu) material. Further, the second metal layer 130 may be made of a gold (Au) or nickel (Ni) material. Further, the oxidation layer 150 may be formed by a brown oxidation process.

Further, the insulating layer 110 may include a unit region and a dummy region. Although not shown, the printed circuit board 100 may further include an adhesive layer formed between the first and second metal layers 120 and 130.

According to the preferred embodiment of the present invention, since the oxidation layer is formed instead of a solder resist in order to protect the metal layer corresponding to a circuit layer formed at the outermost layer of the printed circuit board, close adhesion between the printed circuit board and epoxy molded compounds (EMCs) at the time of a packaging process may be significantly increased.

Further, in the printed circuit board to which the oxidation layer is applied, a warpage phenomenon generated at the time of the packaging process may be improved.

Method of Manufacturing Printed Circuit Board

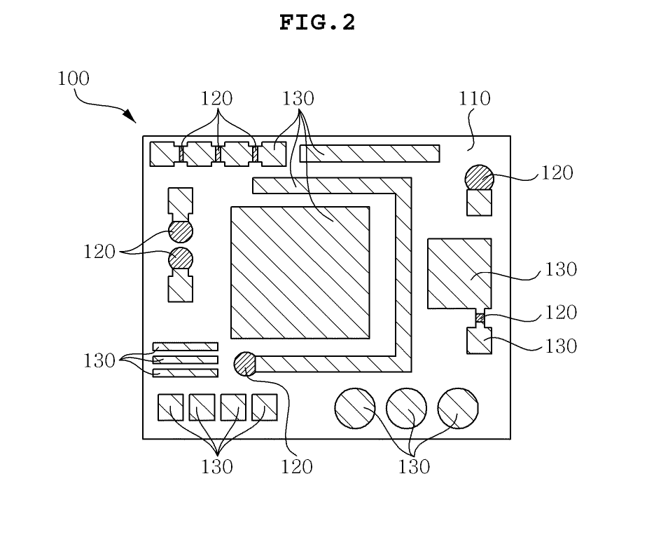

FIGS. 2 to 5 are plan views sequentially showing the process of a method of manufacturing the printed circuit board of FIG. 1.

First, as shown in FIG. 2, the insulating layer 110 may be prepared.

The insulating layer 110 may include a unit region and a dummy region.

In addition, as the insulating layer 110, a resin insulating layer may be used. As materials of the resin insulating layer, a thermosetting resin such as an epoxy resin, a thermoplastic resin such as a polyimide resin, a resin having a reinforcement material such as a glass fiber or an inorganic filler impregnated in them, for example, a prepreg may be used. In addition, a photo-setting resin, and the like, may be used However, the materials of the resin insulating layer are not specifically limited thereto.

Next, the first metal layer 120 may be formed on the insulating layer 110.

The first metal layer 120 may be made of a copper (Cu) material.

In addition, as shown in FIG. 2, the first metal layer 120 has a form in which it is patterned as a circuit pattern and a connection pad.

Although not shown, an adhesive layer (not shown) may be formed between the first and second metal layers 120 and 130.

Next, the second metal layer 130 may be formed on a portion of the first metal layer 120.

Although the case in which the second metal layer 130 is formed on a portion of the first metal layer 120 is shown in FIG. 2 for convenience of explanation, it may be sufficiently analogized that the first metal layer 120 is formed beneath the second metal layer 130.

In addition, materials of the first and second metal layers 120 and 130 may be different from each other.

Further, the second metal layer 130 may be made of a material of which ionization tendency is smaller than that of the first metal layer 120.

For example, the second metal layer 130 may be made of a gold or nickel material.

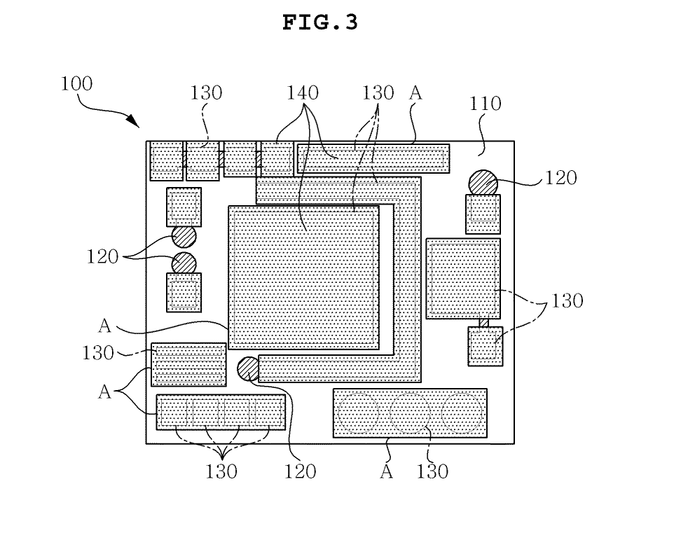

Then, as shown in FIG. 3, a protection layer 140 may be formed on the second metal layer 130.

As shown in FIG. 3, the protection layer 140 may be formed on the second metal layer 130 and be formed so as to cover the entire upper surface of the second metal layer 130 based on a length direction of the substrate.

Here, the protection layer 140 serves to prevent galvanic corrosion induction between the first and second metal layers 120 and 130 of which ionization tendencies are different from each other.

For example, the protection layer 140 may be a dry film However, the protection layer is not limited thereto, but may also be any material capable of enduring a corresponding environment (temperature, component, or the like) at the time of brown oxidation treatment.

The protection layer 140 may be formed on the second metal layer 130 by exposure and development processes, but is not limited thereto.

Meanwhile, although the case in which the protection layer 140 is formed over the entire upper portion of the second metal layer 130 is shown in FIG. 3 by way of example, the present invention is not limited thereto.

For example, in the case in which a region at which the first metal layer 120 is exposed is not present in the pattern connected to the second metal layer 130, a process of forming the protection layer 140 on a corresponding region (a region A of FIG. 3) of the second metal layer 130 may be omitted.

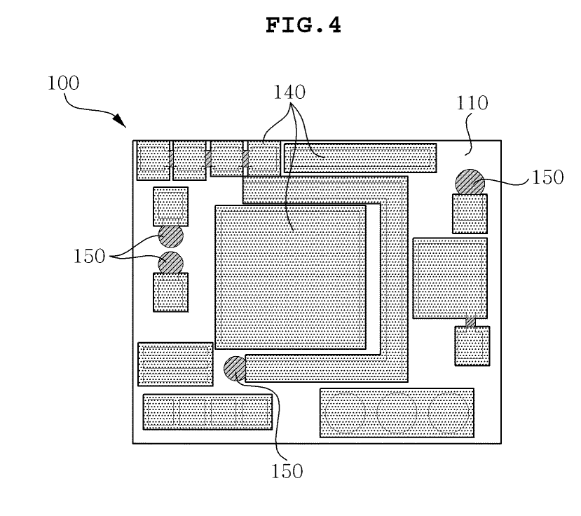

Next, as shown in FIG. 4, the oxidation layer 150 may be formed on a portion of the first metal layer on which the protection layer 140 is not formed.

Here, the oxidation layer 150 may be formed by a brown oxidation process.

In addition, since the second metal layer 130 is covered by the protection layer 140 at the time of the brown oxidation treatment, the second metal layer 130 is not exposed to an electrolyte for the brown oxidation treatment, such that ionization is not made. Therefore, since excessive etching due to a galvanic corrosion phenomenon of the first metal layer 120 caused by ion exchange is not generated, a color change of the oxidation layer 150 may not be generated and roughness may also be preserved at it is.

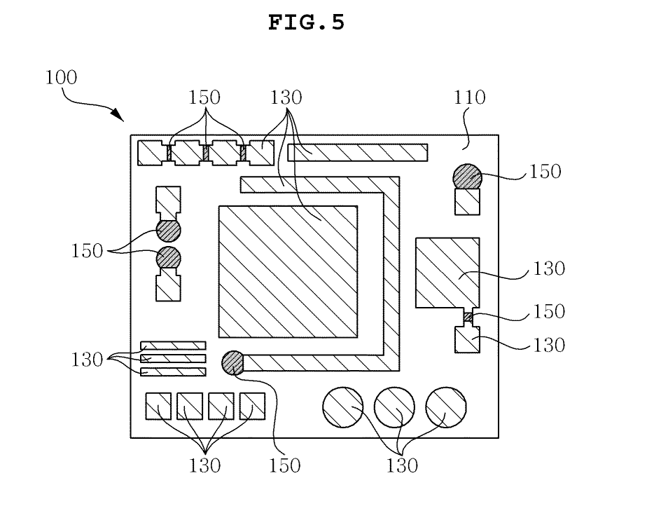

Next, as shown in FIG. 5, the protection layer 140 may be removed.

In this case, the protection layer 140 may be removed using a stripper such as sodium hydroxide (NaOH), potassium hydroxide (KOH), or the like, but is not limited thereto.

According to the preferred embodiment of the present invention, since the oxidation layer is formed instead of a solder resist in order to protect the circuit layer formed at the outermost layer of the printed circuit board, close adhesion between the printed circuit board and epoxy molded compounds (EMCs) at the time of a packaging process may be significantly increased.

Further, in the printed circuit board to which the oxidation layer is applied, a warpage phenomenon generated at the time of the packaging process may be improved.

Further, according to the preferred embodiment, since processes such as a solder resist pretreatment process, a lamination process, an exposure process, a development process, a drying process, and the like, required at the time of a solder resist process are omitted, a process procedure of manufacturing a substrate may be simplified.

Meanwhile, when the brown oxidation process is performed between heterogeneous metal layers (for example, a metal layer made of copper and a metal layer made of gold), etching progresses at a more rapid speed in a specific region of the metal layer made of copper than in other regions of the metal layer made of copper, such that the previously formed anchoring structure is destroyed. Therefore, problems that roughness is decreased, a color is also changed from an existing brown oxidation color to a bright color, and roughness is not formed occur. That is, galvanic corrosion occurs between the heterogeneous metals.

The galvanic corrosion will be described below. At the time of physical contact between heterogeneous metals, unique etching speeds of the respective metals are changed. More specifically, an etching speed of a specific metal is significantly decreased as compared with the case in which only the specific metal is etched; however, an etching speed of another metal is rapidly increased. The phenomenon that the etching speed is rapidly increased as described above is called galvanic corrosion.

The reason is that there is a region at which an etching speed is excessive in a physical contact pattern between the metal layer made of a gold material and the metal layer made of a copper material and an amount of surface current density concentrated on the metal layer made of a copper material according to an area ratio between two metals is significantly increased at a specific portion.

However, according to the preferred embodiment, the present invention, since the protection layer is formed on the second metal layer before the brown oxidation process, at the time of the brown oxidation process performed in an electro-environment, excessive etching due to heterogeneous current density distribution generated in a galvanic corrosion process between the first and second metal layers is prevented, and the destruction of the anchoring structure formed by the brown oxidation process is prevented, thereby making it possible to maintain the roughness and prevent the color change.

With the printed circuit board and the method of manufacturing the same according to the preferred embodiments of the present invention, the oxidation layer is formed on the metal layer of the outermost layer of the printed circuit board in order to protect the outermost layer, thereby making it possible to simplify a process procedure as compared to the solder resist process according to the prior art.

In addition, according to the preferred embodiments of the present invention, the oxidation layer is formed on the metal layer of the outermost layer, such that adhesion between the printed circuit board and a molding member in a packaging process may be improved. Therefore, reliability of the printed circuit board may be improved.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
an insulating layer;
a first metal layer formed on the insulating layer;
a second metal layer formed on a portion of the first metal layer; and
an oxidation layer formed on a portion of the first metal layer on which the second metal layer is not formed,
wherein materials of the first and second metal layers are different from each other, and the second metal layer is made of a material of which ionization tendency is smaller than that of the first metal layer.

2. The printed circuit board as set forth in claim 1, wherein the first metal layer is made of a copper material.

3. The printed circuit board as set forth in claim 1, wherein the second metal layer is made of a gold or nickel material.

4. The printed circuit board as set forth in claim 1, wherein the oxidation layer is formed by a brown oxidation process.

5. The printed circuit board as set forth in claim 1, wherein the insulating layer includes a unit region and a dummy region.

6. The printed circuit board as set forth in claim 1, further comprising an adhesive layer formed between the first and second metal layers.

7. A method of manufacturing a printed circuit board, the method comprising:
preparing an insulating layer;
forming a first metal layer on the insulating layer;
forming a second metal layer on a portion of the first metal layer;
forming a protection layer on the second metal layer;
forming an oxidation layer on a portion of the first metal layer on which the protection layer is not formed; and
removing the protection layer,
wherein materials of the first and second metal layers are different from each other, and the second metal layer is made of a material of which ionization tendency is smaller than that of the first metal layer.

8. The method as set forth in claim 7, wherein in the forming of the first metal layer, the first metal layer is made of a copper material.

9. The method as set forth in claim 7, wherein in the forming of the second metal layer, the second metal layer is made of a gold or nickel material.

10. The method as set forth in claim 7, wherein in the forming of the oxidation layer, the oxidation layer is formed by a brown oxidation process.

11. The method as set forth in claim 7, wherein the insulating layer includes a unit region and a dummy region.

12. The method as set forth in claim 7, further comprising, after the forming of the first metal layer and before the forming of the second metal layer, forming an adhesive layer between the first and second metal layers.

13. The method as set forth in claim 7, wherein in the forming of the protection layer, the protection layer is a dry film.
